(19) United States
(12) Patent Application Publication
(10) Pub. No.: US 2014/0255863 A1
(43) Pub. Date: Sep. 11, 2014

(54) THERMAL TREATMENT APPARATUS

(71) Applicant: KABUSHIKI KAISHA TOSHIBA, Minato-ku (JP)

(72) Inventor: Shingo ABE, Shiga-ken (JP)

(73) Assignee: KABUSHIKI KAISHA TOSHIBA, Minato-ku (JP)

(21) Appl. No.: 14/019,992

(22) Filed: Sep. 6, 2013

(30) Foreign Application Priority Data
Mar. 7, 2013 (JP) 2013-045297

(51) Int. Cl. H01L 21/677; H01L 21/67

(52) U.S. Cl. CPC H01L 21/67742; H01L 21/67098; H01L 21/67748
USPC 432/239

(57) ABSTRACT

An aspect of one embodiment, there is provided a heat treatment apparatus, the apparatus installing a substrate retainer, which retains a plurality of semiconductor substrates in shelf structure, in a thermal treatment furnace to perform heat treatment with respect to the semiconductor substrates, including, a housing, a base plate installed in the housing, a substrate carrier fork placing the semiconductor substrates on the substrate retainer, a vertical shift unit fixed to the base plate, the vertical shift unit vertically driving and moving the substrate carrier fork, a fixing member fixing the base plate to the housing which enable the base plate to vertically move.

### CROSS REFERENCE TO RELATED APPLICATION

This application is based upon and claims the benefit of priority from prior Japanese Patent Application No. 2013-045297, filed on Mar. 7, 2013, the entire contents of which are incorporated herein by reference.

### FIELD

Exemplary embodiments described herein generally relate to a thermal treatment apparatus.

### BACKGROUND

A thermal treatment apparatus, which performs heating a wafer of a semiconductor substrate, includes a carrier installing a number of wafers, a wafer boat (substrate retainer) arranging and supporting the wafers in shelf structure, a heat treatment furnace performing a heat treatment in a state where the wafer boat is installed in the furnace, and a wafer transfer unit transporting the wafer between the carrier and the wafer boat.

The wafer transfer unit includes a transfer fork (so called substrate transfer fork) which installs the wafers, a horizontal transfer unit which transfer the transfer fork in a horizontal direction (X-Y direction), and a vertical transfer unit which transfer the transfer fork in a vertical direction (Z direction).

The vertical transfer unit includes a vertical guide member which guides the transfer fork in the vertical direction. The vertical guide member is fixed to a housing of the thermal treatment apparatus

In such the constitution, the wafer transfer fork in the heat treatment apparatus is inserted between the wafers which are supported by the wafer boat, in a case that the wafers are transported from the wafer boat, which is carried out from the heat treatment furnace, to the carrier after the wafers is performed heat treatment in the thermal treatment apparatus. In such the case, a trouble in which the wafer transfer fork is touched to the wafers may be generated.

### BRIEF DESCRIPTION OF THE DRAWINGS

FIG. 1 is a schematic view showing a constitution of a heat treatment apparatus according to a first embodiment;

FIG. 2 is a vertically cross-sectional view showing the constitution of the heat treatment apparatus from a viewpoint of a side surface according to the first embodiment;

FIG. 3 is a perspective view showing a wafer transfer unit according to the first embodiment;

FIG. 4 is a front view showing a base plate and screws according to the first embodiment;

FIG. 5 is a vertically cross-sectional view showing a state in which the base plate is fixed on a body according to the first embodiment;

FIG. 6 is a vertically cross-sectional view corresponded to FIG. 5 showing a state in which the base plate is thermally expanded according to the first embodiment;

FIG. 7 is a side view showing a state in which a wafer carrier boat is inserted between wafers according to the first embodiment;

FIG. 8 is a perspective view showing a state in which a base plate is fixed on a body according to a second embodiment;

FIG. 9 is a vertically cross-sectional view showing a periphery of a portion in which holding members are fixed on the base plate according to the second embodiment.

### DETAILED DESCRIPTION

An aspect of one embodiment, there is provided a heat treatment apparatus, the apparatus installing a substrate retainer, which retains a plurality of semiconductor substrates in shelf structure, in a thermal treatment furnace to perform heat treatment with respect to the semiconductor substrates, including, a housing, a base plate installed in the housing, a substrate carrier fork placing the semiconductor substrates on the substrate retainer, a vertical shift unit fixed to the base plate, the vertical shift unit vertically driving and moving the substrate carrier fork, a fixing member fixing the base plate to the housing which enable the base plate to vertically move.

Embodiments will be described below in detail with reference to the attached drawings mentioned above. Throughout the attached drawings, similar or same reference numerals show similar, equivalent or same components, and the description is not repeated. As drawings are schematic and conceptual, a relation between a thickness and a length of each portion or a ratio between portions is not necessary to identify with the corresponding real value. Further, it is not restricted to represent same size or ratio in a case of pointing out the same portion in the drawings, accordingly, the same size or ratio is differently represented in the drawings.

### First Embodiment

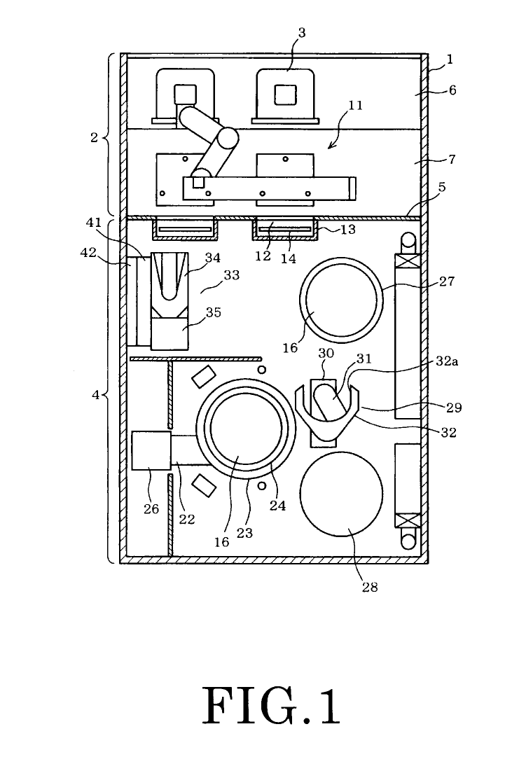

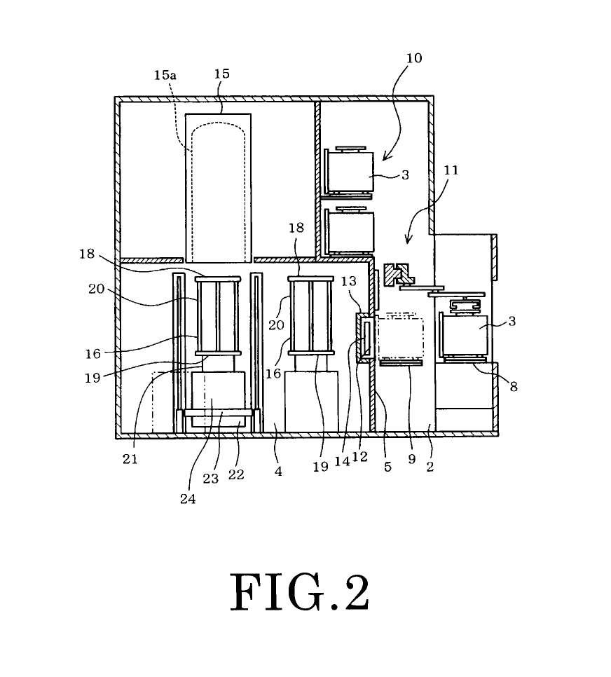

In the description mentioned below, explanation is performed on a heat treatment apparatus with a vertical type according to a first embodiment in reference to FIGS. 1-7. FIG. 1 is a plane view showing an inner portion of the heat treatment apparatus. FIG. 2 is a vertically cross-sectional view showing the heat treatment apparatus from a viewpoint of a right side in FIG. 1.

A thermal treatment apparatus includes an installing area 2 and a loading area 4 in a housing 1 which constitutes an exterior body. A carrier 3 installing wafers, which is semiconductor substrates, is carried in/out from the installing area 2 to the thermal treatment apparatus. The carrier 3 is installed in a thermal furnace described below from the loading area 4. A wall 5 is place between the installing area 2 and the loading area 4 to separate the two areas. The installing area 2 is retained at atmospheric air and the loading area 4 is retained at clean and dry air which has less particles, organic components, and further a dew point below 60° C., for example.

The installing area 2 includes a first area 6 and a second area 7. A first pedestal 8, on which the carrier 3 is disposed, is placed in the first area 6. A transport case, which is called FOUP, is used as the carrier 3. FOUP is composed of resin, for example, and has a cap body to block an install window at a front panel (not shown). A plurality of wafers W of semiconductor substrates, each of which having a 300 mm diameter, is installed in the carrier to be arranged in shelf structure. A second pedestal 9, a carrier holding unit 10 and carrier transfer unit 11 are placed in the second area 7. The carrier transfer unit 11 transfers the carrier 3 between a first pedestal 8, the second pedestal 9, and the carrier holding unit 10.

As shown in FIG. 1, an opening 12 is configured in the wall 5 to communicate with the carrier 3 and the loading area 4. The opening 12 is opened and closed by a door 13. A cap body of the carrier 3 is opened and closed by a cap opening unit.

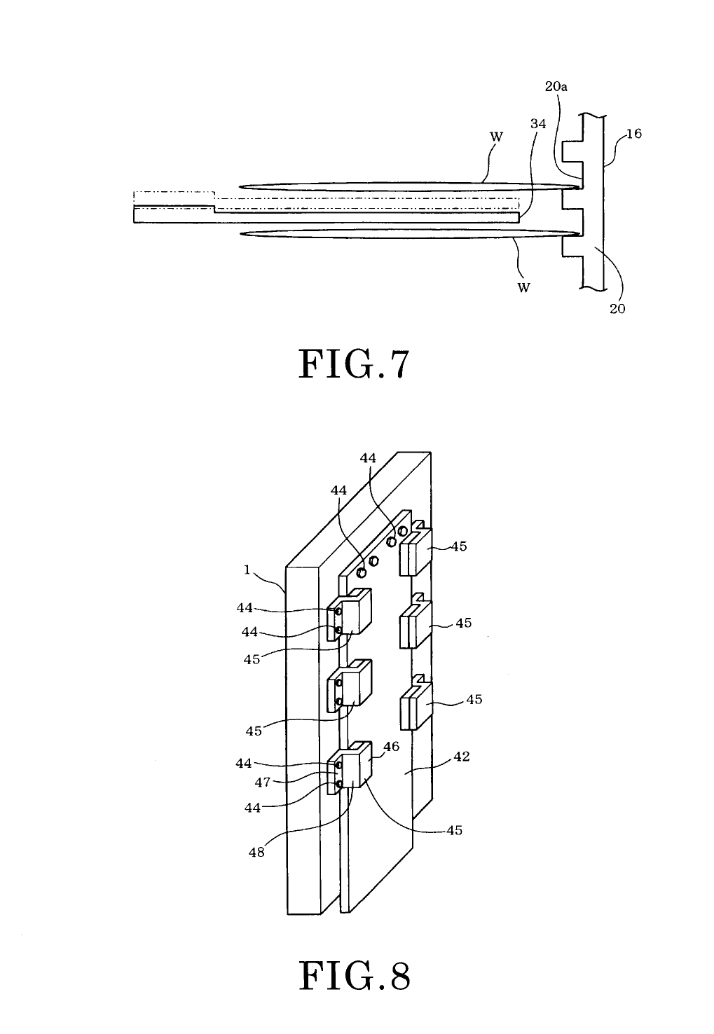

A thermal treatment furnace 15 with a vertical type is placed at an upper side of the loading area 4, and a lower end of the thermal treatment furnace 15 is configured to be opened as a furnace window. Two wafer boats 16 are placed in the loading area 4. Each of the two wafer boats 16 is constituted that the plurality of the wafers W are configured to arranged and retained as the shelf structure. Here, the constitution of the wafer boat 16 is simply described. A plurality of pillars is placed between a top board and a bottom board. As shown in FIG. 7, a periphery portion of the wafer W is retained at a groove portion formed in each of the pillars. In such a structure, nearly a hundred of the wafers W can be vertically arranged with a prescribed interval to be retained. A supporting unit 21 is placed at a lower portion of the bottom board to support the bottom board.

Three of stages are arranged in the loading area 4 to be placed the wafer board 16. One of the stages is placed on a boat elevator 22, which is an up/down unit of a substrate retainer and is arranged at a lower side of the thermal treatment furnace 15. The boat elevator 22 is constituted to freely move up and down. A cap body 23 of the thermal treatment furnace 15 and a heat insulating material 24 as a stage material are placed in order on the boat elevator 22. The heat insulating 24 is constituted quartz or the like, and the wafer boat 16 is placed on the heat insulating 24.

The boat elevator 22 is constituted to freely move up and down by a movement unit along a guide rail (not shown) configured to be vertically extended. In such a manner, the wafer boat 16 is moved up and down between a load and an unload positions. At the load position, the wafer boat is installed in a reaction case 15a of the thermal treatment furnace 15 and the opening of the thermal treatment furnace 15 is covered with the cap body 23. At the unload position, the wafer boat 16 is carried out to the lower side of the thermal treatment furnace 15. The two positions are indicated in FIGS. 1 and 2.

Furthermore, a first stage 27 and a second stage 28 are arranged as stages. The wafer boat 16 is disposed on the first stage 27 when the wafer W is transferred between the wafer boat 16 and the carrier 3 on the second pedestal 9. The wafer boat 16 is tentatively disposed on the second stage 28, before and after the wafer boat 16 is performed to be thermally treated in the thermal treatment furnace 15.

Furthermore, a boat transfer unit 29 is arranged in the loading area 4 to transfer the wafer boat 16 between the boat elevator 22, the first stage 27, and the second stage 28. The boat transfer unit 29 is used as a holding member transfer unit. As shown in FIG. 1, the boat transfer unit 29 includes a multi-jointed arm 31 in driving unit 30. The multi-jointed arm 31 is constituted to move freely up and down, to rotate freely around the rotational axis and to move freely front and back. A holding arm 32 is placed on a leading edge of the multi-jointed arm 31. The holding arm 32 has nearly U-shape in plane, and the opening 32a of the holding arm 32 is larger than the supporting unit of the wafer boat 16 and smaller than the bottom board 19.

As shown in FIG. 1, the boat transfer unit 29 is arranged a portion between the first stage 27 and the second stage 28 in the embodiments. Further, the boat elevator 22 is arranged at a left side of the boat transfer unit 29 to be set on the unload position. The holding arm 32 surrounds the supporting unit 21 of the wafer boat 16, which is a moving object, in the boat transfer unit 29. The holding arm 32 is moved upwards to lift up to move the bottom board 19. In the reverse manner mentioned above, the wafer boat 16 is transferred to the stage to be transferred. In this case, the wafer boat 16 configured to be tentatively transferred from the stage to be originally positioned to the boat transfer unit 29, successively, to be transferred to the stage to be transferred.

A wafer transfer unit (substrate transfer unit) 33 is arranged a portion at a near side to the installing area 2 in the loading area 4 to be adjacent to the first area 27. The wafer transfer unit 33 is configured to perform transfer the wafer W between the wafer boat 16 on the first stage 27 and the carrier 3 on the second pedestal 9.

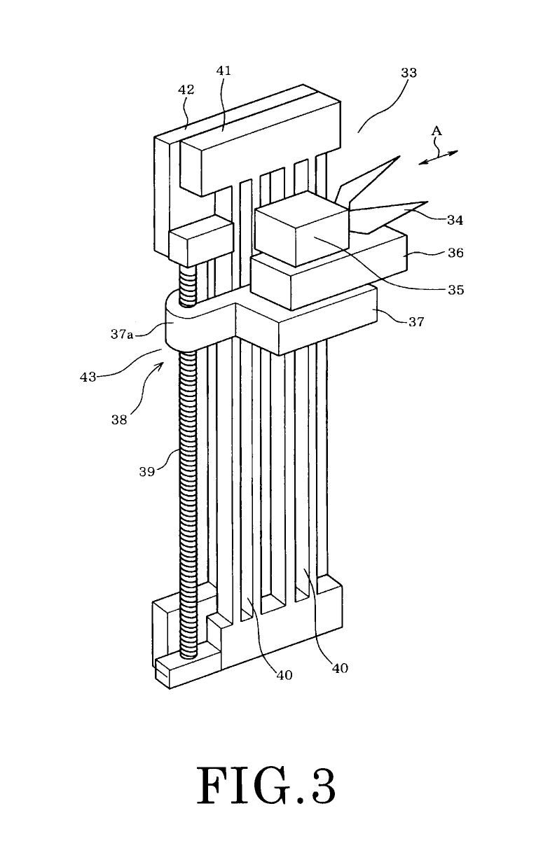

As shown in FIG. 3, the wafer transfer unit 33 includes a fork (substrate carrier fork) 34, a fork support body 35, a shift support body 36, a rotation support body 37, and a vertical shift unit 38. The fork holds the wafer W. The fork support body 35 supports the fork 34. The shift support body 36 is configured to move the fork support body 35 in an arrow direction A. The rotation support body 37 can rotationally move the shift support body 36 around vertical axis to support the shift support body 36. The vertical shift unit 38 is constituted to include a screw axis 39 of a ball screw 43 and a driving plate 41 including two guide rails 40. The driving plate 41 is placed to a base plate 42.

The ball screw is constituted with a screw axis 39 and a nut portion 37a provided at the rotation support body 37. Two guide convex portions (not shown) provided at the rotation support body 37 are slidably fitted to the guide rail 40 so that the rotation support body 37 is guided by the guide rail 40 to be able to vertically move. In such a constitution, the screw axis 39 of the ball screw 43 is driven to rotate by a motor (not shown). Accordingly, a rotation support body 37, namely the nut portion 37a, corresponded to a rotational amount and a rotational direction of the screw axis 39 can be precisely drive to move up and down.

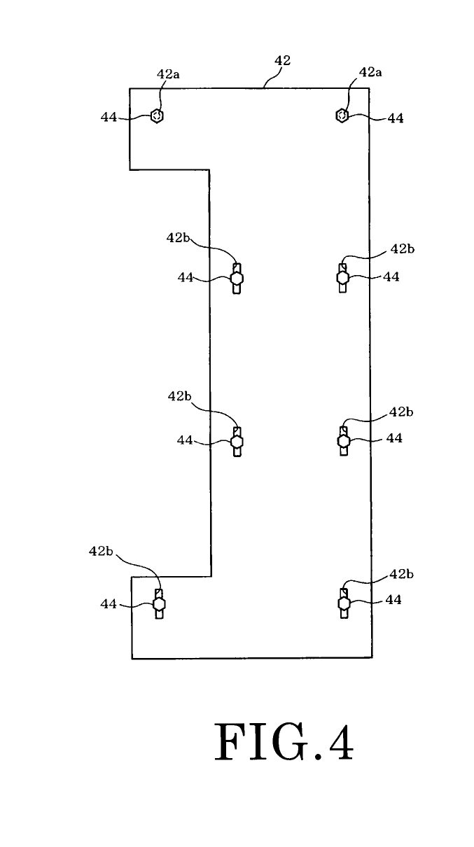

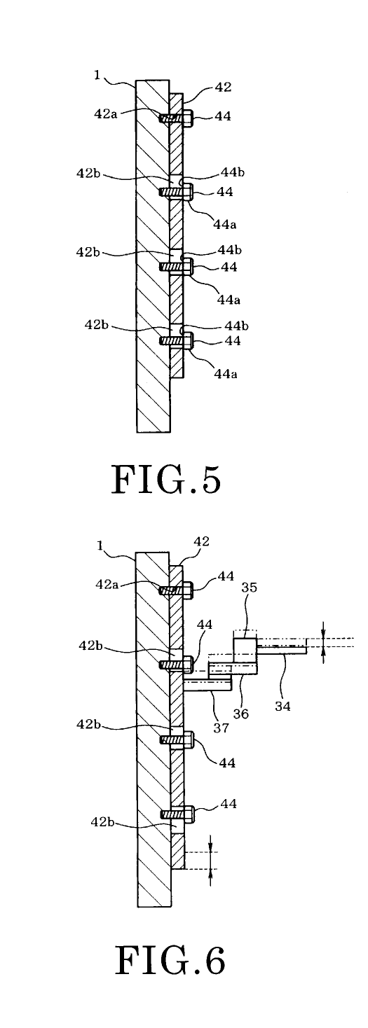

The base plate 42 is screwed on the housing 1 of the thermal treatment apparatus. Actually, as shown in FIG. 4, two through holes 42, for example, is formed on an upper end portion of the base plate 42 and six long holes 42b are thoroughly formed to be inserted by screws on a middle portion and a lower end portion. A number of the through holes 42a, 42b can be suitably changed corresponding to a material, size or the like of the base plate 42. In such a case, as shown in FIG. 5, the base plate is in contact with the housing 1, and each of the screws 44 are inserted into each of the through holes 42a and the long holes 42b of the base plate 42, and the inserted screws 44 are screwed to be fixed on the base plate 42. In such the constitution, the long holes 42 and screws 44 constitute the fixing members.

A material, which has smaller friction coefficient than that of the screw 44, is coated on a surface of a head portion 44a of the screw 44 being in contact with the base plate. As a material with smaller friction coefficient, polytetrafluoroethylene, nylon, ployoxymethylene, or the like as resin, or molybdenum alloy or the like as metal can be used. In case of resin, it is necessary to select a material having a melting point which can sustain in the highest temperature of atmosphere in which the base plate is placed. Instead of coating a material having smaller friction coefficient than that of a material of the screw 44 on the head portion 44a of the screw 44, the material having smaller friction coefficient than that of a material of the screw 44 can be coated on a periphery of the opening of the long hole 42b of the base plate 42, the periphery of the opening being contact with the head portion 44a of the screw 44. A material of the base plate 42 is composed of cast alloy of aluminum and magnesium, for example, and a material of the housing 1 is composed of steel, for example. A material of the screw 44 is composed of iron, stainless steel, brass, aluminum alloy, titanium or the like.

Here, processes, in which the wafers W is transferred to the carrier 3 by wafer transfer unit 33 from the wafer boat 16 carried out from the thermal treatment furnace 15, are explained. First, a temperature of the wafer boat 16, immediately after carrying out from the thermal treatment furnace 15, is nearly 600-800° C. However, the wafer boat 16 is cooled by an air cooling unit (not shown) in the loading area 4 so that a temperature near the wafer transfer unit 33 is 60-80° C., for example. In such the case, as the temperature near the wafer transfer unit 33 is 60-80° C., the base plate 42 thermally expanded as compared to the housing 1. Because, thermal expansion coefficient of the base plate 42 is larger than that of the housing 1 in the thermal treatment apparatus. In this embodiment, the material of the base plate 42 is composed of Al—Mg cast alloy which has thermal expansion coefficient of 25×10⁻⁶. On the other hand, the material of the housing 1 is composed of steel which has thermal expansion coefficient of 11.7×10⁻⁶.

Therefore, the base plate and the housing are distorted to warp when the base plate is completely fixed to the housing so that the fork is tilted in upper or lower direction. As a result, the fork may be in contact with the wafer when the fork is inserted between the wafer boat and wafer.

On the other hand, when one end portion of the base plate 42, only an upper end portion, for example, is fixed to the housing 1, the screw 44 is screwed via the long hole 42b in the other end portion in this embodiment. As the base plate 42 is pressed to the housing 1 as shown in FIG. 6, the base plate 42 can be thermally expanded to the housing 1 to move freely to the lower portion. In such a manner, the base plate is not caused to be distorted to warp in contrast to the conventional case while the base plate 42 is thermally expanded. Consequently, the fork 34 of the wafer transfer unit 33 can be prevented from tilt to retain horizontal level of the fork 34 in reference to FIGS. 5-7. Accordingly, the fork can be prevented from being in contact with the wafer when the fork 34 is inserted between the wafers W supported by the wafer boat. Note that two-dot chain line in FIGS. 6-7 indicates the position of the fork 34 before thermal expansion of the base plate 4.

A thermal treatment apparatus also can include a position detection unit (not shown) to detect the position of the fork 34 in this embodiment. When the base plate 42 is thermally expanded to shift the position in the vertical direction, laser or the like is irradiated the portion which the base plate 42 is expanded, the lower portion, for example, to detect the reflection light. In such a manner, the position shift of the fork 34 in the vertical direction can be detected on a basis of the detection signal to correct the position shift in reference to FIG. 7. The constitution of the position detection unit is not restricted to the laser irradiation and the reflection light detection approach. A constitution of image recognition by camera or detecting the position of the fork 34 in the vertical direction by a contact-type censor can be used. As another case, instead of the position detection unit which detects the position of the fork 34 in the vertical direction, the position detection unit which detects the position of the base plate 42 in the vertical direction can be used in the constitution.

### Second Embodiments

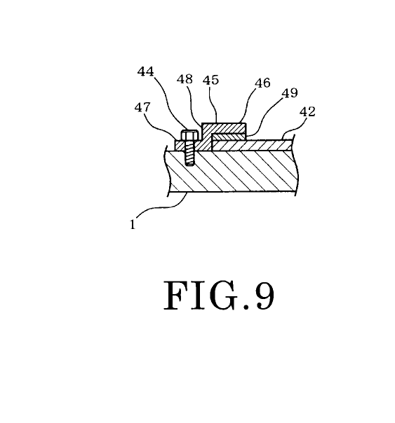

A second embodiment is shown in FIGS. 8, 9. In the second embodiment, similar or same reference numerals as the first embodiment show similar, equivalent or same components, and the description is not repeated. In a constitution of the second embodiment, instead of the long hole 42b and the screw 44, a holding member (fixing member) 45 are used.

Specifically, each of the holding members 45 includes a holding portion 46, a fixing portion 47, and a connection portion 48. The holding portion 46 presses the base plate 42. The fixing portion is screwed on the housing. The connection portion 48 connects the holding portion 46 and the fixing portion 47. A sliding member 49 is touched on an inner surface of the holding portion 46, the inner surface is in contacting with the base plate 42. A material of the sliding member 49 has smaller friction coefficient than that of a material of the holding member 45. Polytetrafluoroethylene, nylon, ployoxymethylene, or the like as resin, or molybdenum alloy or the like as metal can be used as the material.

When the base plate 42 is placed on the housing 1 by using the holding members 45 described above, an upper end of the base plate 42 is fixed to the housing 1 by screwing four screws 44 as shown in FIG. 8. The holding portions 46 of the holding members 45 are in contact with the base plate 42 at three points by one side, summing up both sides to six points, to press the base plate so that the fixing portions 47 of the holding member 45 are screwed to the housing 1 by the screws 44 to be fixed. A number of the holding members 45 can be suitably changed corresponding to a length of the base plate 42, thermal effect to the base plate 42 in the thermal treatment or the like.

Other constitutions of the second embodiment are the same as those of the first embodiment. Accordingly, the second embodiment can also obtain the same effects of the first embodiment. Note that only the base plate 42 and the housing are shown while the driving plate 41, the vertical shift unit 38, the fork or the like are omitted in FIG. 8.

### Other Embodiments

Another constitution described below can be employed in addition to the embodiments described above. In the first embodiment described above, the material having smaller friction coefficient than that of the material of the screw 44 is coated on the surface 44b of the head portion 44a of the screw 44. However, it is not restricted to the above case. A washer composed of a material having smaller friction coefficient than that of the material of the screw 44 can be used or a washer having a coated surface, the coating material having smaller friction coefficient than that of the material of the screw 44 can be arranged between the head portion 44a of the screw 44 and the base plate 44.

In the first embodiment, the upper end portion of the base plate 42 is fixed to the housing not to move the base plate. However, the fixing is not restricted to the above case. The middle portion or the lower end portion of the base plate 42 can be fixed to the housing 1 by the screws 44 not to move the base plate 42. The long holes 42b are used as all of the holes and the base plate 42 is fixed by screws 44 so that the base plate can be movable without unmovable as described above.

In the second embodiment, the sliding member 49 is composed of the material having smaller friction coefficient than that of the material of the holding member 45. However, the fixing is not restricted to the above case. The surface of the sliding member 49, especially, a surface being in contact with the base plate 42, is coated by a material having smaller friction coefficient than that of the material of the holding member 45. A material having smaller friction coefficient than that of the holding member can be coated on an inner surface of the holding portion 46 of the holding member 45, the inner surface being in contact with the base plate 42. A material having smaller friction coefficient than that of the material of the holding member can be coated on a surface of the base plate 42, especially, the surface of the holding member 45 being in contact with the holding portion 46

Furthermore, the upper end portion of the base plate 42 is fixed to the housing 1 by the screws 44 not to move the base plate 42 in the second embodiment. However, the fixing is not restricted to the above case. The middle portion or the lower end portion of the base plate 42 can be fixed to the housing 1 by the screws 44 not to move the base plate 42.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A heat treatment apparatus, the apparatus having a substrate retainer, which retains a plurality of semiconductor substrates in shelf structure, in a thermal treatment furnace to perform heat treatment with respect to the semiconductor substrates, comprising:
a housing;
a base plate installed in the housing;
a substrate carrier fork placing the semiconductor substrates on the substrate retainer;
a vertical shift unit fixed to the base plate, the vertical shift unit vertically driving and moving the substrate carrier fork;
a fixing member fixing the base plate to the housing which enables the base plate to vertically move.

2. The apparatus of claim 1, wherein
the fixing member has a long hole formed and vertically extending in the base plate, and a screw inserted in the long hole.

3. The apparatus of claim 2, wherein
a surface portion of a head portion of the screw, the surface portion being in contact with the base plate, is coated with a coating material having smaller friction coefficient than friction coefficient of a material of the screw.

4. The apparatus of claim 3, wherein
the coating material is composed of one selected from polytetrafluoroethylene, nylon, ployoxymethylene and molybdenum alloy.

5. The apparatus of claim 2, wherein
a coating material having smaller friction coefficient than friction coefficient of a material of the screw is coated on a periphery portion of an opening of the long hole.

6. The apparatus of claim 5, wherein
the coating material is composed of one selected from polytetrafluoroethylene, nylon, ployoxymethylene and molybdenum alloy.

7. The apparatus of claim 2, further comprising:
a washer inserted between the screw and the base plate, wherein the washer is composed of a material having smaller friction coefficient than friction coefficient of a material of the screw.

8. The apparatus of claim 2, further comprising:
a washer inserted between the screw and the base plate,
wherein the washer is coated with a coating material which has smaller friction coefficient than friction coefficient of a material of the screw.

9. The apparatus of claim 5, wherein
the coating material is composed of one selected from polytetrafluoroethylene, nylon, ployoxymethylene and molybdenum alloy.

10. The apparatus of claim 1, wherein
the fixing member includes a holding portion pressing the base plate, a fixing portion screwed on the housing, and a connection portion connecting the holding portion and the fixing portion.

11. The apparatus of claim 10, wherein
a surface portion of the holding portion, the surface portion being in contact with the base plate, is composed of a material having friction coefficient than friction coefficient of a material of the fixing member

12. The apparatus of claim 10, wherein
a surface portion of the holding portion, the surface portion being in contact with the base plate, is coated with a material having smaller friction coefficient than friction coefficient of a material of the fixing member.

13. The apparatus of claim 10, wherein
a sliding member is placed on a surface portion of the holding portion, the surface portion being in contact with the base plate, friction coefficient of the sliding member is smaller than friction coefficient of the fixing member.

14. The apparatus of claim 10, wherein
a sliding member is placed on a surface portion of the holding portion, the surface portion being in contact with the base plate, and the sliding member is coated with a coating material having smaller friction coefficient than friction coefficient of a material of the fixing member.

15. The apparatus of claim 10, wherein
a surface portion of the holding portion, the surface portion being in contact with the base plate, is coated with a coating material having smaller friction coefficient than friction coefficient of a material of the holding member.

16. The apparatus of claim 1, further comprising;
a fixing member fixing the base plate which is configured not to move to the housing.

17. The apparatus of claim 16, further comprising;
the fixing member is placed an upper portion from the fixing member in the base plate.

18. The apparatus of claim 1, further comprising;
a detector, the detector detects a position of the substrate carrier fork to be configured to shift the position of the substrate carrier fork to a prescribed position, when the position is out of alignment.

19. The apparatus of claim 18, further comprising;
detection approach of the detector is one selected from a method of detecting reflection light by using laser, detecting an image by using a video equipment, and detecting apposition by using a censer.
